(19) United States
(12) Patent Application Publication
(10) Pub. No.: US 2015/0207001 A1
(43) Pub. Date: Jul. 23, 2015

(54) COLORED GLASS AND SOLAR CELL ASSEMBLY USING THE SAME

(71) Applicant: CHANGZHOU ALMADEN CO., LTD., Changzhou (CN)

(72) Inventors: Jinxi Lin, Changzhou (CN); Jinhan Lin, Changzhou (CN); Ling Chen, Changzhou (CN); Guoxiang Wang, Changzhou (CN); Zhilong Ni, Changzhou (CN)

(21) Appl. No.: 14/550,542

(22) Filed: Nov. 21, 2014

(30) Foreign Application Priority Data
Nov. 22, 2013 (CN) 201310597314.X

(51) Int. Cl. H01L 31/049; H01L 31/048

(52) U.S. Cl. CPC H01L 31/049; H01L 31/0488

(57) ABSTRACT

The subject invention is related to a colored glass and a solar cell assembly comprising the same. The subject invention provides a colored glass comprising a glass substrate; and a colored coating formed on the glass substrate, wherein the colored coating comprises an inorganic film-forming material, a pigment and an adhesive. The subject invention also provides a solar cell assembly comprising: a front glass substrate; the aforementioned colored glass; and a photovoltaic cell sealed between the front glass substrate and the colored glass. The colored glass of the subject invention has a good thermal conductivity, improved waterproof performance, mechanical properties and weather resistance such that the colored glass is not only aesthetically pleasing but also useful as a backside protection material of a solar cell assembly for long-term outdoor use.

### BACKGROUND

1. Field of the Invention

The subject invention is related to a colored glass, particularly a colored glass having a good thermal conductivity, improved, or preferably excellent, waterproof performance, mechanical properties, weather resistance, and usability as a backside protection material for a solar cell assembly.

2. Description of the Related Art

Due to global warming and other environmental problems resulting from exploitation of fossil fuels and carbon dioxide emissions, there is an urgent need in industry to find clean and efficient alternative energy sources as a replacement for coal, or to ease the consumption of fossil fuels. Solar energy is found to be clean and environmentally friendly, and has become one of the promising alternative energy sources.

Generally, a solar cell assembly comprises a front glass to receive the sunlight upon exposure and protect the underlying solar cells, and a backside protection material to support the solar cells, wherein sealant such as ethylene vinyl acetate copolymer (EVA) may be used to hold the front glass, the solar cells, and the backside protection material together.

For solar cell assemblies which are designed for long-term outdoor use, particularly for a period up to 20 years, weather resistance and waterproof performance of the front glass and the backside protection material used in the solar cell assemblies are crucial. It is known that glass has excellent weather resistance and waterproof performance and is suitable for use as a backside protection material in solar cell assemblies in different environments, such as in a desert or on a beach. In order to make the appearance of a solar cell assembly more appealing and pleasing to the public, and to fit into the surroundings where the solar cell assembly is located, glass which not only scientifically shows desirable properties for long-term outdoor use but also is aesthetically decorative to the surroundings is needed, and development of various glasses having different colors are desirable and have to be developed.

Attempts were made in the art to develop colored glass for use in solar cell assembly. A Chinese patent application, CN 1272517 A, discloses a colored coating for glasses, which comprises organic compounds as main components and a small amount of inorganic particles; said colored coating is however designed for indoor use such as windows, light bulbs and ornaments, rather than outdoor use. A Chinese utility model patent, CN 202678354 U, discloses a dual-glass crystallized silicon solar cell, which shows various colors by forming an optical medium film on the solar cell and selectively absorbing the light of a specific wavelength. However such optical medium film has to be formed using a complicated chemical vapor deposition process.

Given the aforementioned problems left in the prior art, there is still a need to develop colored glass for use in solar cell assembly for long-term outdoor use.

### SUMMARY

The subject invention provides a colored glass with a good thermal conductivity, improved, or preferably excellent, waterproof performance, mechanical properties, and weather resistance, which not only shows an aesthetically pleasing appearance, but also meets the requirements for long-term outdoor use. Such colored glass not only imparts a solar cell assembly comprising such colored glass with outstanding appearance, allowing the appearance of the solar cell assembly to be changed, but also fulfills the need for developing a colored solar cell assembly for long-term outdoor use.

The subject invention also provides a colored glass which can be manufactured using simple techniques at low cost, and is suitable for mass production.

Specifically, the subject invention is directed to a colored glass comprising: a glass substrate; and a colored coating formed on the glass substrate, wherein the colored coating comprises an inorganic film-forming material, a pigment and an adhesive. The subject invention is also directed to a solar cell assembly comprising: a front glass substrate; the aforementioned colored glass as the backside protection material; and a photovoltaic cell sealed between the front glass substrate and the aforementioned colored glass.

### BRIEF DESCRIPTION OF THE DRAWINGS

FIG. 1 shows the structure of the colored glass according to an embodiment of the subject invention.

FIG. 2 shows the structure of a solar cell according to an embodiment of the subject invention.

It should be noted that elements in the drawing are not depicted according to the ratio of their actual sizes.

### DETAILED DESCRIPTION OF THE INVENTION

In this context, unless otherwise limited, a singular term (such as “a”) also includes a plural form thereof. In this context, all embodiments and exemplary terms (for example, “such as”) are not intended to limit the scope of the present invention; terms in this specification should not be construed as implying that any component not claimed may form a necessary component for implementing the present invention.

Other than in any operating examples, or where otherwise indicated, all numbers expressing quantities of ingredients, reaction conditions and so forth used in the specification and claims are to be understood as being modified in all instances by the term “about.” Accordingly, unless indicated to the contrary, the numerical parameters set forth in the following specification and attached claims are approximations that may vary depending upon the desired properties to be obtained by the present invention. It should be understood that any numerical range recited herein is intended to include all sub-ranges and numbers subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10, such as 1.2 to 8.8 or 0.6398 to 7.5135, and numbers, such as 5.65452 . . . or 8. At the very least, and not as an attempt to limit the application of the doctrine of equivalents to the scope of the claims, each numerical parameter should at least be construed in light of the number of reported significant digits and by applying ordinary rounding techniques.

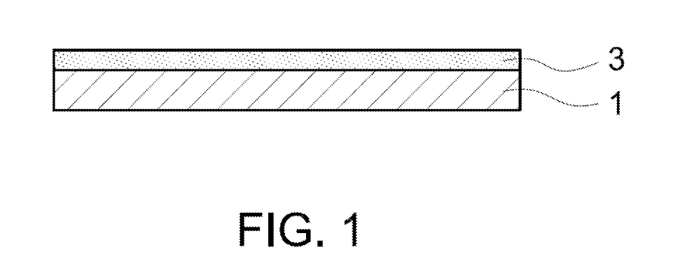

As shown in FIG. 1, according to one of the embodiments of the subject invention, the colored glass of the subject invention comprises: a glass substrate 1; and a colored coating 3 formed on the glass substrate, wherein the colored coating comprises an inorganic film-forming material, a pigment and an adhesive.

According to one of the embodiments of the subject invention, the glass substrate may be any suitable materials in the art including, but not limited to, a plate glass or a calendered glass.

According to one of the embodiments of the subject invention, the glass may be subjected to a tempered treatment, a half-tempered treatment, a tempered heat treatment, a half-tempered heat treatment, a physical tempered treatment or a half-physical tempered treatment; or not subjected to any of the foregoing treatments.

According to one of the embodiments of the subject invention, the glass substrate has a thickness of at least about 0.2 mm.

According to one of the embodiments of the subject invention, the inorganic film-forming material may be any suitable materials in the art including, but not limited to, SiO₂, ZrO₂, BaSO₄, Al₂O₃, CaCO₃, CaSO₄, ZnO, Pb₃O₄, Sb₂O₃, TiO₂, MgO, MgCO₃, mica, lead white, talc or a combination thereof. The inorganic film-forming material has a particle size of about 0.001 μm to about 50 μm, preferably about 0.1 μm to about 5 μm, more preferably about 0.2 μm to about 3 μm.

Based on the total weight of the colored coating, the inorganic film-forming material has a content of about 3% to about 40%, preferably about 4% to about 20%, more preferably about 10% to about 18%.

According to one of the embodiments of the subject invention, the pigment may be any suitable inorganic pigments in the art including, but not limited to, an iron yellow pigment, an iron red pigment, an iron black pigment, an iron blue pigment, a cobalt yellow pigment, a cobalt green pigment; a cadmium yellow pigment, a cadmium red pigment, an ultramarine blue pigment or a combination thereof; or any suitable organic pigments in the art including but not limited to a fast yellow pigment, a benzidine yellow pigment, a nickel azo yellow pigment, a zinc titanium white pigment, a phthalocyanine blue pigment, a phthalocyanine green pigment, pigment scarlet powder, a quinacridone red pigment or a combination thereof.

According to one of the embodiments of the subject invention, based on the total weight of the colored coating, the pigment has a content of about 0.1% to about 20%, preferably about 3% to about 17%, more preferably about 5% to about 15%.

According to one of the embodiments of the subject invention, the adhesives may be any suitable materials in the art including, but not limited to, colloids made from alcohol alcoholate (such as tetrabutyl titanate, tetraethyl orthosilicate or tetramethyl orthosilicate), organic salts (such as Pb(CH₃COO)₂), inorganic salts (such as Zn(NO₃)₂ and zirconium oxychloride) and/or organicmetallic compounds; organic polymers, for example, novolac resins, urea-formaldehyde resins, expoxy resins, polyvinyl acetate, polyvinyl acetate acetate, polyurethane, acrylate, polystyrenes, alkyd resins, polyisocyanate, diacrylate, silanes, polybenzimidazole, polyimide, butyl rubber, and tetrabutyl orthosilicate; and a combination thereof. By the total weight of the colored coating, the content of the adhesives is from about 3% to about 40%, preferably from about 4% to about 20%, more preferably from about 10% to about 18%.

Optionally, the colored coating of the subject invention may comprise one or more of the following additives: catalysts or auxiliaries. The auxiliaries may be items such as emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, defoamers or a combination thereof.

The content of the auxiliaries, if added, is from about 0.1% to about 20%, preferably from about 1% to about 18%, more preferably from about 5% to about 16% based on the total weight of the colored coating.

In addition, the colored coating of the subject invention may optionally comprise a solvent.

The aforementioned catalysts may be any suitable materials in the art including, but not limited to, inorganic acids, organic acids, bases, acidic salts, basic salts or organic ammonium salts or a combination thereof.

The content of the catalysts, if added, is from about 0.1% to about 1%, preferably from about 0.3% to about 0.8%, more preferably from about 0.4% to about 0.7% based on the total weight of the colored coating.

The aforementioned solvents may be any suitable materials in the art including but not limited to, water, petroleum solvents, benzene solvents, terpene solvents, alcohol solvents, ether solvents, ketone solvents, ester solvents, chlorinated hydrocarbon solvents, nitro hydrocarbon solvents or amine solvents or a combination thereof.

The content of the solvents, if added, is from about 20% to about 70%, preferably from about 25% to about 65%, more preferably from about 35% to about 50% based on the total weight of the colored coating.

According to one of the embodiments of the subject invention, the colored glass of the subject invention is prepared by a process comprising: (1) providing a glass substrate; (2) coating a surface of the glass substrate with a colored coating composition comprising an inorganic film-forming material, a pigment and an adhesive; (3) curing the coated glass substrate.

According to one of the embodiments of the subject invention, the inorganic film-forming material, pigment and adhesives are mixed at a specific ratio at a temperature of about 0° C. to about 60° C., preferably about 15° C. to about 50° C., more preferably about 25° C. to about 40° C., for a period from about 0.2 hour to about 48 hours, preferably for about 3 hours to 20 hours, more preferably for 5 hours to 10 hours (depending on the adopted temperature). In other words, the time period will vary depending on the temperature chosen, e.g., higher temperatures may require less time. When the mixture is homogeneously mixed, catalysts are added, and the mixing is carried out for about 0.2 hours to about 48 hours, preferably for about 5 hours to 25 hours, more preferably for 10 hours to 20 hours.

According to one of the embodiments of the subject invention, the colored coating composition is applied onto the surface of the glass substrate by roll coating, spray coating, dip coating, slot coating, spin coating, printing, supersonic atomization or a combination thereof.

According to one of the embodiments of the present invention, the coated glass substrate is cured at a temperature from about 0° C. to about 800° C., preferably from about 150° C. to about 500° C., more preferably from about 200° C. to about 450° C. for a curing period from about 30 seconds to about 60 hours, preferably about 2 minutes to about 1 hour, more preferably about 2 minutes to about 0.5 hour (depending on the adopted curing temperature).

According to one of the embodiments of the subject invention, the colored coating on the coated glass substrate has a thickness of about 0.2 μm to about 200 μm.

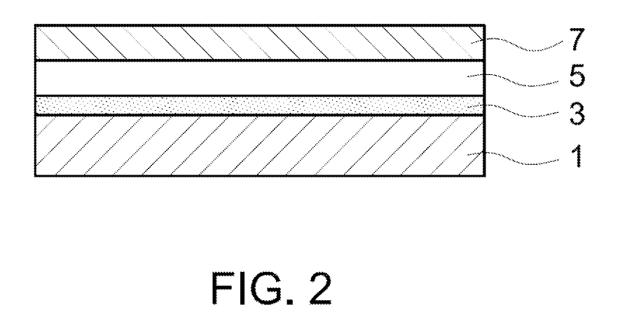

According to one of the embodiments of the subject invention, the solar cell assembly of the subject invention comprises: a front glass substrate; a colored glass; and a photovoltaic cell sealed between the front glass substrate and the colored glass. In a preferred embodiment as illustrated in FIG. 2, the colored glass 1, 3 may act as a backside coating glass. The photovoltaic cell 5 is sealed between the backside coating glass (1, 3) and the front glass substrate 7.

According to one of the embodiments of the subject invention, the solar cell assembly may comprise thermoplastic materials, such as but not limited to ethyl vinyl acetate (EVA), filled between the front glass substrate and photovoltaic cells and between the photovoltaic cells and the backside coating glass.

Although according to the foregoing description, the solar cell assembly of the subject invention has the foregoing structure, it is only for illustrative purposes and is not intended to limit the present invention.

Except for the colored glass of the subject invention, the solar cell assembly may be prepared by any conventional methods.

### EXAMPLES

The colored coatings prepared according to the embodiments of the subject invention have the following compositions.

| | Example 1 | Example 2 |
|---|---|---|
| Ingredients | (Mass percentage %) | (Mass percentage %) |
| Inorganic | 10% SiO₂ of a particle | 6% Al₂O₃ of a particle |
| film- | size from about | size of about 1 μm |
| forming | 0.5 μm to about 2 μm | |
| materials | | |
| | 5% BaSO₄ of a particle | 8% SiO₂ of a particle size |
| | size from about | from about 0.5 μm to |
| | 0.5 μm to about 2 μm | about 2 μm |
| Pigments | 10% iron blue | 5% nickel azo yellow |
| | | 5% cadmium yellow |
| Adhesives | 10% | 7% tetraethyl orthosilicate |
| | γ-methacryloxypro- | |
| | pyltrimethoxysilane | |
| | 5% acrlyate | 8% polyurethane |
| Auxiliaries | 5% dispersants | 5% thickening agents |
| | 2% light stabilizers | 3% anti-skinning agents |
| | 2% abrasion resistant | 2% anti-settling agents |
| | 2% defoamers | 1% abrasion resistant |
| | | 3% defoamers |
| | | 1% anti-shrinking agents |
| catalysts | 0.5% HCl | 0.6% oxalic acid |
| solvents | 20% water | 16% water |
| | 20% ethanol | 24% isopropanol |
| | 5% ethylene glycol | 5.4% diethylamine |
| | 3.5% isopropanol | |

### Example 1

The colored coating is obtained by mixing the inorganic film-forming materials, pigments, adhesives, auxiliaries and solvents according to the ratios set forth above, at 30° C. for 6 hours; and stirring for 16 hours after the addition of catalysts.

### Example 2

The colored coating is obtained by mixing the inorganic film-forming materials, pigments, adhesives, auxiliaries and solvents according to the ratios set forth above at 40° C. for 6 hours; and stirring for 16 hours after the addition of catalysts.

### Example 3

The colored coating composition of Example 1 is applied onto a surface of the glass substrate by spray coating, and the coated glass substrate is baked at 250° C. for 20 minutes to obtain a colored glass.

### Example 4

The colored coating composition of Example 2 is applied onto a surface of the glass substrate by roll coating, and the coated glass substrate is baked at 400° C. for 10 minutes to obtain a colored glass.

The colored glass of the subject invention has better weather resistance due to the presence of a large amount of inorganic film-forming material and shows various colors. Such colored glass not only provides a colored solar cell assembly with various visual appearance options but also meets the requirements for long-term outdoor use and broadens the extent of the applications of a colored solar cell assembly.

The coating process used in the subject invention is simple and carried out at low cost, and thus is suitable for mass production.

It should be understood that the foregoing description and the appended drawing are given for illustration and reference only, without any intention to limit the scope of the present invention. The scope of the invention should only be limited by the appended claims. Various changes and modifications within the spirit and scope of the invention will become apparent to those skilled in the art from this detailed description.

What is claimed is:

1. A colored glass comprising: a glass substrate; and a colored coating formed on the glass substrate, wherein the colored coating comprises an inorganic film-forming material, a pigment and an adhesive.

2. The colored glass according to claim 1, wherein based on the total weight of the colored coating, the inorganic film-forming material has a content of about 3% to about 40%; the pigment has a content of about 0.1% to about 20%; and the adhesive has a content of about 3% to about 40%.

3. The colored glass according to claim 1, wherein the inorganic film-forming material is selected from the group consisting of SiO₂, ZrO₂, BaSO₄, Al₂O₃, CaCO₃, CaSO₄, ZnO, Pb₃O₄, Sb₂O₃, TiO₂, MgO, MgCO₃, mica, lead white, and talc.

4. The colored glass according to claim 1, wherein the pigment is selected from the group consisting of an iron yellow pigment, an iron red pigment, an iron black pigment, an iron blue pigment, a cobalt yellow pigment, a cobalt green pigment; a cadmium yellow pigment, a cadmium red pigment, an ultramarine blue pigment, a fast yellow pigment, a benzidine yellow pigment, a nickel azo yellow pigment, a zinc titanium white pigment, a phthalocyanine blue pigment, a phthalocyanine green pigment, pigment scarlet powder, and a quinacridone red pigment.

5. The colored glass according to claim 1, wherein the inorganic film-forming material has a particle size of about 0.001 μm to about 50 μm.

6. The colored glass according to claim 1, wherein the adhesive is selected from the group consisting of a colloid formed from alcoholates, organic salts, inorganic salts, and/or organometallic compounds, and organic polymers.

7. The colored glass according to claim 1, wherein the colored glass further comprises additives and/or solvents, wherein the additives are selected from the group consisting of catalysts, emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, and defoamers.

8. The colored glass according to claim 1, wherein the glass substrate is a plate glass or a calendered glass.

9. The colored glass according to claim 1, wherein the colored coating has a thickness of about 0.2 μm to about 200 μm.

10. A solar cell assembly comprising:
a front glass substrate;
a colored coating formed on a back glass substrate to produce a colored glass, wherein the colored coating comprises an inorganic film-forming material, a pigment and an adhesive; and
a photovoltaic cell sealed between the front glass substrate and the colored glass.

11. A solar cell assembly according to claim 10, wherein based on the total weight of the colored coating, the inorganic film-forming material has a content of about 3% to about 40%; the pigment has a content of about 0.1% to about 20%; and the adhesive has a content of about 3% to about 40%.

12. A solar cell assembly according to claim 10, wherein the inorganic film-forming material is selected from the group consisting of SiO₂, ZrO₂, BaSO₄, Al₂O₃, CaCO₃, CaSO₄, ZnO, Pb₃O₄, Sb₂O₃, TiO₂, MgO, MgCO₃, mica, lead white, and talc.

13. A solar cell assembly according to claim 10, wherein the pigment is selected from the group consisting of an iron yellow pigment, an iron red pigment, an iron black pigment, an iron blue pigment, a cobalt yellow pigment, a cobalt green pigment; a cadmium yellow pigment, a cadmium red pigment, an ultramarine blue pigment, a fast yellow pigment, a benzidine yellow pigment, a nickel azo yellow pigment, a zinc titanium white pigment, a phthalocyanine blue pigment, a phthalocyanine green pigment, pigment scarlet powder, and a quinacridone red pigment.

14. A solar cell assembly according to claim 10, wherein the inorganic film-forming material has a particle size of about 0.001 μm to about 50 μm.

15. A solar cell assembly according to claim 10, wherein the inorganic film-forming material has a particle size of about 0.001 μm to about 50 μm.

16. A solar cell assembly according to claim 10, wherein the colored glass further comprises additives and/or solvents, wherein the additives are selected from the group consisting of catalysts, emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, and defoamers

17. A solar cell assembly according to claim 10, wherein the glass substrate is a plate glass or a calendered glass.

18. A solar cell assembly according to claim 10, wherein the colored coating has a thickness of about 0.2 μm to about 200 μm.

19. The colored glass according to claim 1, wherein the inorganic film-forming material comprises any combination of two or more of the following: SiO₂, ZrO₂, BaSO₄, Al₂O₃, CaCO₃, CaSO₄, ZnO, Pb₃O₄, Sb₂O₃, TiO₂, MgO, MgCO₃, mica, lead white, and talc.

20. The colored glass according to claim 1, wherein the pigment comprises any combination of the following: an iron yellow pigment, an iron red pigment, an iron black pigment, an iron blue pigment, a cobalt yellow pigment, a cobalt green pigment; a cadmium yellow pigment, a cadmium red pigment, an ultramarine blue pigment, a fast yellow pigment, a benzidine yellow pigment, a nickel azo yellow pigment, a zinc titanium white pigment, a phthalocyanine blue pigment, a phthalocyanine green pigment, pigment scarlet powder, and a quinacridone red pigment
